(19) United States
(12) Patent Application Publication
(10) Pub. No.: US 2007/0218215 A1
(43) Pub. Date: Sep. 20, 2007

(54) Plasma processing method and color filter manufactured by using the same and process for manufacturing color filter by using the same

(75) Inventors: Hiroki Sakata, Tokyo (JP); Yusuke Uno, Tokyo (JP); Norikatsu Nakamura, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: DAI NIPPON PRINTING CO., LTD., Tokyo (JP)

(21) Appl. No.: 11/717,617

(22) Filed: Mar. 14, 2007

(30) Foreign Application Priority Data
Mar. 15, 2006 (JP) 2006-071185

(51) Int. Cl. C23C 16/24

(52) U.S. Cl. 427/589

(57) ABSTRACT

The present invention provides a plasma processing method capable of being used for manufacturing color filters which are substantially free from defects such as white spots and color mixture of inks and color filters manufactured by using the same. A plasma processing device according to the present invention comprises a stage mainly acting also as a lower electrode; and a head electrode in which an upper electrode is stored and from which plasma raw material gas is ejected. By ejecting plasma raw material gas from the head electrode, applying voltage between the stage and the head electrode by an alternate power source to induce plasma electric discharge and by scanning over a workpiece material (glass substrate) by the head electrode, the workpiece material (glass substrate) is subjected to the plasma processing. When delivering the workpiece material (glass substrate) to the next process after the plasma processing has been completed, a lifting frame contacting with the periphery of the workpiece material (glass substrate) is used.

### CROSS REFERENCE TO RELATED APPLICATIONS

This application is based upon the description, drawings and abstract of prior Japanese Patent Application No. 2006-71185, filed on Mar. 15, 2006, the entire contents of which are incorporated herein by reference.

### BACKGROUND OF THE INVENTION

1. Field of the Invention

The present invention relates to a plasma processing method which is optimally used in a plasma processing process in a color filter manufacturing process and a color filter manufactured by using the same.

2. Description of the Related Art

In manufacturing a color filter used for a fluorescent display unit, a plasma display unit and a liquid crystal display unit, it has been proposed to apply inks of red, blue and green between lattices of black matrices laminated on a glass substrate by means of an ink-jet method to form a color pattern. For a technology of manufacturing a color filter in this manner, there is disclosed, for example, in JP-A-9-230127, a manufacturing method of color filter, comprising the steps of forming convex portions on a substrate, depositing ink to concave portions divided by the convex portions by means of the ink-jet method and laminating ink in the concave portions thereby forming colored layers, wherein after having formed the convex portions, the concave portions are made ink-attracting by means of etching processing and then ink is sprayed by means of the ink-jet method.

In such a manufacturing method of color filter, as a pre-step before forming ink films by means of the ink-jet method, a step of giving ink-shedding quality to the lattice portions of the black matrices on the glass substrate and giving ink-attracting quality to the glass surface between the lattices of the black matrices is provided. However, it is considered to employ a normal pressure plasma processing in this step. For example, in JP-A-2002-320845, there is disclosed a normal pressure plasma processing device comprising a pair of opposing upper and lower electrodes and a power source applying pulsed electric field between the pair of electrodes, wherein at least one opposing surface of the pair of opposing electrodes is covered with a solid dielectric material, the upper electrode is smaller than the lower electrode, and the lower electrode is a large flat plate electrode.

### SUMMARY OF THE INVENTION

The normal pressure plasma processing device for performing plasma processing of giving ink-shedding quality to the lattice portions of the black matrices on the glass substrate and giving ink-attracting quality to the glass surface between the lattices of the black matrices in the pre-step of before forming ink films by means of the ink-jet method will be further described.

With reference to FIGS. 10 to 12, the outline of such a conventional normal pressure plasma processing device will be described. FIG. 10 is a view schematically showing the essential parts of a conventional normal pressure plasma processing device 50 used for manufacturing color filters. FIG. 11 is a view showing a state in which a workpiece material (glass substrate) 56 has been lifted by a lift pin 54 in the conventional normal pressure plasma processing device 50. FIG. 12A is a perspective view showing the conventional normal pressure plasma processing device 50 used for manufacturing color filters. FIG. 12B is an enlarged view showing the workpiece material (glass substrate) 56 laid on a stage (lower electrode) 53 on the periphery of the lift pin 54.

In FIGS. 10 to 12, numeral 56 denotes a glass substrate as a workpiece material to be plasma processed. On this substrate, black matrices (not shown) are laminated. Numeral 53 denotes an aluminum stage on which the glass substrate as the workpiece material is to be laid. This stage also functions as a lower electrode at the time of plasma processing. Numeral 51 denotes a head electrode which includes a mechanism for ejecting tetrafluoromethane (carbon tetrafluoride, CF₄), nitrogen gas or a mixture gas thereof as a raw material gas for plasma processing, and stores an upper electrode corresponding to the lower electrode. By applying a power source between these upper electrode and lower electrode, the raw material gas is plasmatized. The head electrode 51 is configured to be driven in direction X as shown by a driving source (not shown) to scan over the glass substrate 56 as the workpiece material equally, thereby enabling plasma processing to be performed on the glass substrate. Numeral 52 denotes an AC power source capable of applying an AC voltage of about 1 to 50 kHz between the head electrode (upper electrode) 51 and the stage (lower electrode) 53. Numeral 54 denotes a lift pin which is a mechanism for lifting the workpiece material (glass substrate) 56 before and after the plasma processing step performed by the plasma processing device 50 and is connected to an actuator as a driving source for lifting the lift pin 54. After the plasma processing step by the plasma processing device 50, the workpiece material (glass substrate) 56 is delivered to a processing device for ink film forming process by means of the ink-jet method. At this time, as shown in FIG. 11, a delivery arm (not shown) is inserted, for example, in direction F in the figure, below the workpiece material (glass substrate) 56 lifted by the lift pin 54, and the workpiece material (glass substrate) 56 is delivered to the next step with being laid on this delivery arm.

Meanwhile, the inventors et al. have now knowledge that there easily occur problems on a workpiece material (glass substrate) 56 on the periphery of the lift pin 54 due to plasma processing for a workpiece material (glass substrate) 56 laid on the stage (lower electrode) 53. Now, these problems will be described in detail. FIG. 12B is an enlarged view showing the workpiece material (glass substrate) 56 laid on a stage (lower electrode) 53 on the periphery of the lift pin 54. For the workpiece material (glass substrate) 56 on the stage (lower electrode) 53, it is conceivable that the surface to be processed A of the workpiece material (glass substrate) 56 laid on the lift pin 54 and the surface to be processed B of the workpiece material (glass substrate) 56 laid on the other area of the stage (lower electrode) 53 will have different electric discharge characteristics from each other at the time of plasma processing. Therefore, neither suitable ink-shedding quality is given to the lattice portions of the black matrices (not shown) laminated within the area of the surface to be processed A by means of plasma processing, nor suitable ink-attracting quality is given to the glass substrate surface between the black matrix lattices within the area of the surface to be processed A by means of plasma processing. Thus, in the ink film forming step by means of the ink-jet method after the plasma processing step, it is known that there occurs a problem that no ink is applied suitably to the glass substrate surface between the black matrix lattices existing within the area of the surface to be processed A. As a concrete phenomena, no ink spreads wettably and sufficiently over the openings between the black matrix lattices existing within the area of the surface to be processed A, there occurs color-absent places, so-called white fall-offs of inks, or a state in which no suitable color performance is exerted due to mixed inks, a so-called color mixture state is produced. As a result, there is caused a problem of a low-quality and low-yield color filter.

The present invention has been made to solve the above problems, and the invention according to claim 1 is a plasma processing method comprises the steps of: laying a workpiece material on a lower electrode of opposing electrode composed of an upper electrode and a lower electrode; plasma-processing the workpiece material by means of plasma generated by introducing gas for plasma processing between the upper electrode and the lower electrode and applying voltage between the upper electrode and the lower electrode; and lifting the plasma-processed workpiece material by a lifting means from the lower electrode on which the workpiece material is placed, wherein the lifting means contacts with the portion of the workpiece material other than effective utilization areas thereof.

According to claim 2, the plasma processing method as described in claim 1, wherein the lifting means contacts with the periphery of the workpiece material that is an area other than the effective utilization areas thereof.

According to claim 3, the plasma processing method as described in claim 2, wherein the lifting means contacts with two sides of the periphery of the workpiece material that is an area other than the effective utilization areas thereof.

According to claim 4, the plasma processing method as described in claim 2, wherein the lifting means contacts with four sides of the periphery of the workpiece material that is an area other than the effective utilization areas thereof.

According to claim 5, the plasma processing method as described in any of claims 1 to 4, wherein the lifting means does not come into contact with the workpiece material at the time of plasma processing.

According to claim 6, the plasma processing method as described in any of claims 1 to 5, wherein the lifting means includes a lift pin coming into contact with the workpiece material in the area of the lower electrode.

The invention according to claim 7 is a color filter manufactured by means of a plasma processing method as described in any of claims 1 to 6.

The invention according to claim 8 is the process for manufacturing color filter by means of a plasma processing method according to any of claims 1 to 6.

In the plasma processing method according to the present invention, since the lifting means for lifting the workpiece material in carrying in and out the workpiece material is configured to contact with a portion of the workpiece material other the effective utilization areas thereof. The method can be applied for manufacturing a color filter which is substantially free from defects such as white spots and color mixture of inks. Further, the color filter according to the present invention manufactured by means of such a plasma processing method is substantially free from defects such as white spots and color mixture of inks.

### BRIEF DESCRIPTION OF THE DRAWINGS

FIG. 1 is a view showing the outline of the essential parts of a plasma processing device 10 used in a plasma processing method according to an embodiment of the present invention;

FIG. 2 is a perspective view showing a plasma processing device 10 used in a plasma processing method according to an embodiment of the present invention;

FIG. 3 is an enlarged sectional view schematically showing a workpiece material (glass substrate) 16;

FIG. 4 is an enlarged sectional view schematically showing a state in which a head electrode 11 is scanning over the workpiece material (glass substrate) 16 with being driven by a driving source (not shown);

FIG. 5 is an enlarged sectional view showing the workpiece material (glass substrate) 16 which has been subjected to an ink film forming step;

FIG. 6 is an enlarged sectional view schematically showing the head electrode 11 arranged opposed to a stage (lower electrode) 13;

FIG. 7 is a view showing a state in which the workpiece material (glass substrate) 16 is lifted by a lifting frame 14 in the plasma processing device 10 used in the plasma processing method according to the present embodiment;

FIG. 8 is a view showing the outline of the essential parts of a plasma processing device 10′ in a plasma processing method according to another embodiment of the present invention;

FIG. 9 is a perspective view showing the plasma processing device 10′ in the plasma processing method according to another embodiment of the present invention;

FIG. 10 is a view showing the outline of the essential parts of a conventional normal pressure plasma processing device 50 having been used in the manufacturing step of color filters;

FIG. 11 is a view showing a state in which the workpiece material (glass substrate) 56 having been lifted by a lift pin 54 in the conventional normal pressure plasma processing device 50;

FIG. 12A is a perspective showing the conventional normal pressure plasma processing device 50 used in the manufacturing step of color filters; and

FIG. 12B is an enlarged view showing the workpiece material (glass substrate) 56 laid on the stage (lower electrode) 53 on the periphery of the lift pin 54.

### DETAILED DESCRIPTION OF THE PREFERRED EMBODIMENTS

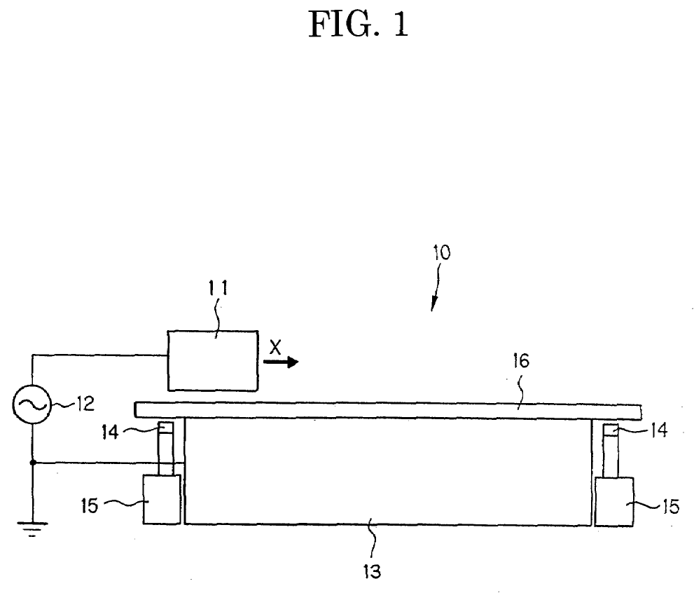

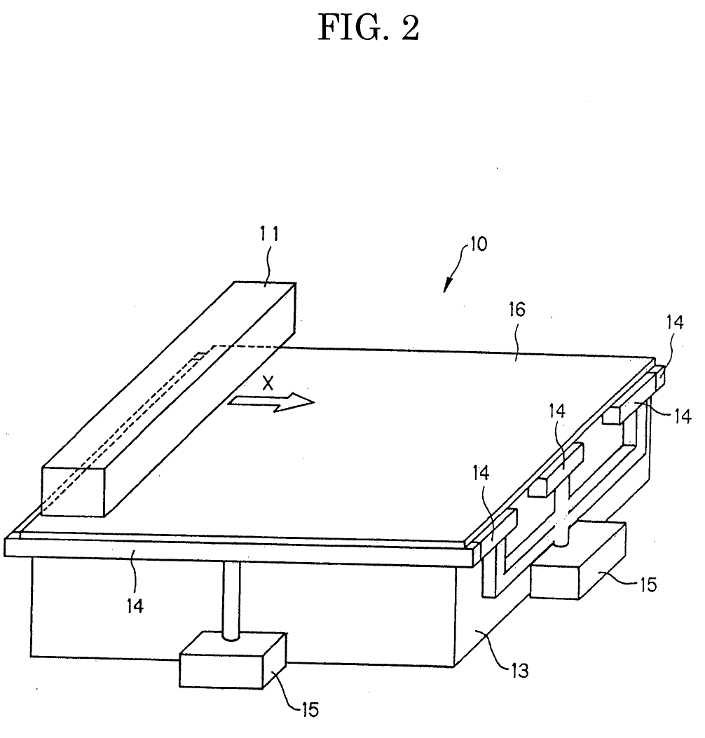

Now, embodiments of the present invention will be described below with reference to the accompanying drawings. FIG. 1 is a view showing the outline of the essential parts of a normal pressure plasma processing device 10 used in a plasma processing method according to an embodiment of the present invention. FIG. 2 is a perspective view showing a plasma processing device 10 used in a normal pressure plasma processing method according to an embodiment of the present invention.

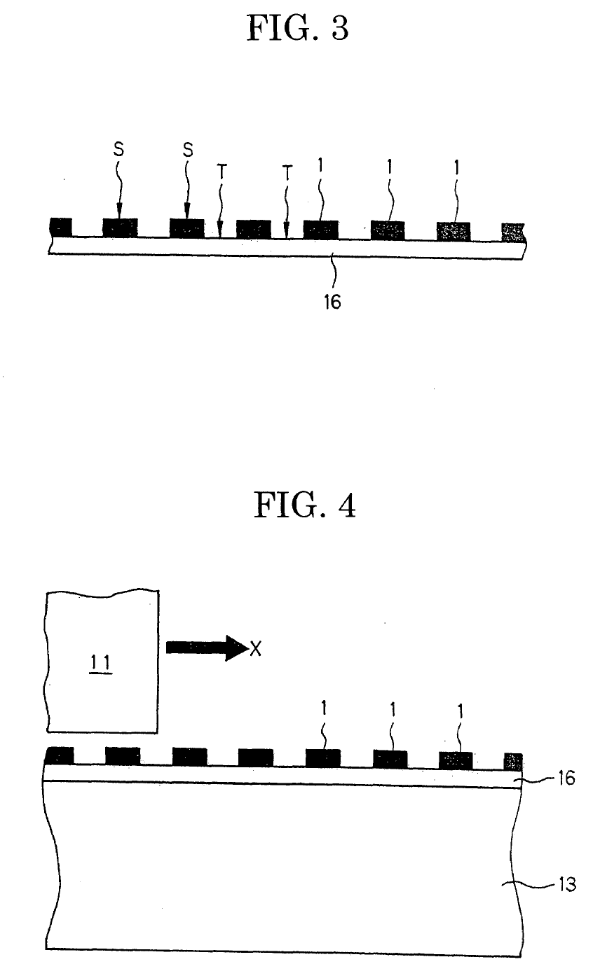

In FIGS. 1 and 2, numeral 16 denotes a glass substrate that is a workpiece material to be plasma-processed. On this workpiece material (glass substrate) 16, black matrices (not shown) are formed with being laminated to compose a color filter. FIG. 3 is an enlarged sectional view schematically showing this workpiece material (glass substrate) 16. As shown in FIG. 3, black matrices 1 are formed to be laminated on the workpiece material (glass substrate) 16.

The black matrices 1 are used as barriers for preventing mixture of inks of red, blue and green, have preferably a thickness of equal to or more than 0.5 μm, use a photosensitive resin composite containing resin (including photopolymeric monomer and photopolymeric initiator), a black light shielding material, a dispersant and a solvent as main ingredients, and are preferably formed by patterning using a photolithography method. Meanwhile, the method of forming the black matrices 1 is not limited to the photolithography method, and various methods may also be used, such as heat transfer method and printing method.

Plasma processing of this workpiece material (glass substrate) 16 by the plasma processing device 10 has an object of, as a pre-step before forming ink films by means of an ink-jet method, giving ink-shedding quality to lattice portion surfaces (S) of the black matrices on the glass substrate and giving ink-attracting quality to the glass surfaces (T) between the lattices of the black matrices.

The plasma processing device 10 includes an aluminum stage (lower electrode) 13 on which the workpiece material (glass substrate) 16 is placed and a head electrode 11 to perform such plasma processing. The aluminum stage 13 also functions as a lower electrode. The head electrode 11 includes a mechanism for ejecting tetrafluoromethane (carbon tetrafluoride, CF₄), nitrogen gas or a mixture gas thereof as a raw material gas for plasma processing, and stores an upper electrode corresponding to the lower electrode. By applying high frequency voltage between the upper electrode and lower electrode, the raw material gas is electrically discharged to be plasmatized. Numeral 12 denotes an AC power source capable of applying an AC voltage of about 1 to 50 kHz between the head electrode (upper electrode) 11 and the stage (lower electrode) 13.

Between the head electrode 11 and the workpiece material (glass substrate) 16, there is provided a predetermined gap. In this gap space electric discharge is induced to plasmatize the raw material gas, thereby subjecting the workpiece material (glass substrate) 16 to the plasma processing. The head electrode 11 is configured to be driven in direction X as shown in the figure by a driving source (not shown) to scan over the glass substrate 16 (workpiece material) equally, thereby enabling plasma processing to be performed on the glass substrate. FIG. 4 is an enlarged sectional view schematically showing a state in which a head electrode 11 is scanning over the workpiece material (glass substrate) 16 with being driven by a driving source (not shown).

In the plasma processing step in the plasma processing device 10 used in the plasma processing method according to the present embodiment, a plasma processing (CF₄ plasma processing) is performed in the air atmosphere with tetrafluoromethane (carbon tetrafluoride, CF₄), nitrogen gas or a mixed gas thereof as a raw material gas. In addition, the raw material gas is not limited to tetrafluoromethane (carbon tetrafluoride, CF₄), and gasses of compounds containing other fluorine atoms may also be used. Gasses of compounds containing such fluorine atoms include CF₄, CHF₃, C₂F₆, C₃F₈ and C₅F₈. A plurality of combinations of halogen gasses selected from the above-described gasses or a plurality of combinations of inert gasses such as N₂ and halogen gasses may be used. By means of this CF₄ plasma processing, a fluorine group is introduced onto the lattice portion surfaces (S) of the black matrices, thereby giving ink-shedding quality to the surfaces (S). On the other hand, the etching effect of this CF₄ plasma processing gives ink-attracting quality to the glass surfaces (T) between the lattices of the black matrices.

Now, the structure of the head electrode 11 will be described. FIG. 6 is an enlarged sectional view schematically showing the head electrode 11 arranged opposed to the stage (lower electrode) 13. In the head electrode 11, there are provided a ejection hole 24 for ejecting tetrafluoromethane (carbon tetrafluoride, CF₄), nitrogen gas or a mixed gas thereof as a raw material gas toward an electric discharging portion and a discharge hole 25 for discharging the gas after having been used for the plasma processing. Numeral 20 denotes a stainless steel upper electrode opposed to the stage (lower electrode) 13, and the outer circumference thereof is covered with an aluminum case 22. Moreover, numeral 21 denotes a dielectric material substrate made of a ceramic plate or the like. The tetrafluoromethane (carbon tetrafluoride, CF₄), nitrogen gas or a mixed gas thereof as a raw material gas for the plasma processing introduced from a flow path P, is ejected onto the workpiece material (glass substrate) 16 from the ejection hole 24 and is plasmatized in an electric discharge area D between the upper electrode 20 and the stage (lower electrode) 13, thereby plasma-processing the surface of the workpiece material (glass substrate) 16. The gas after having been used for the plasma processing is discharged from the discharge hole 25 into a flow path Q as shown in the figure.

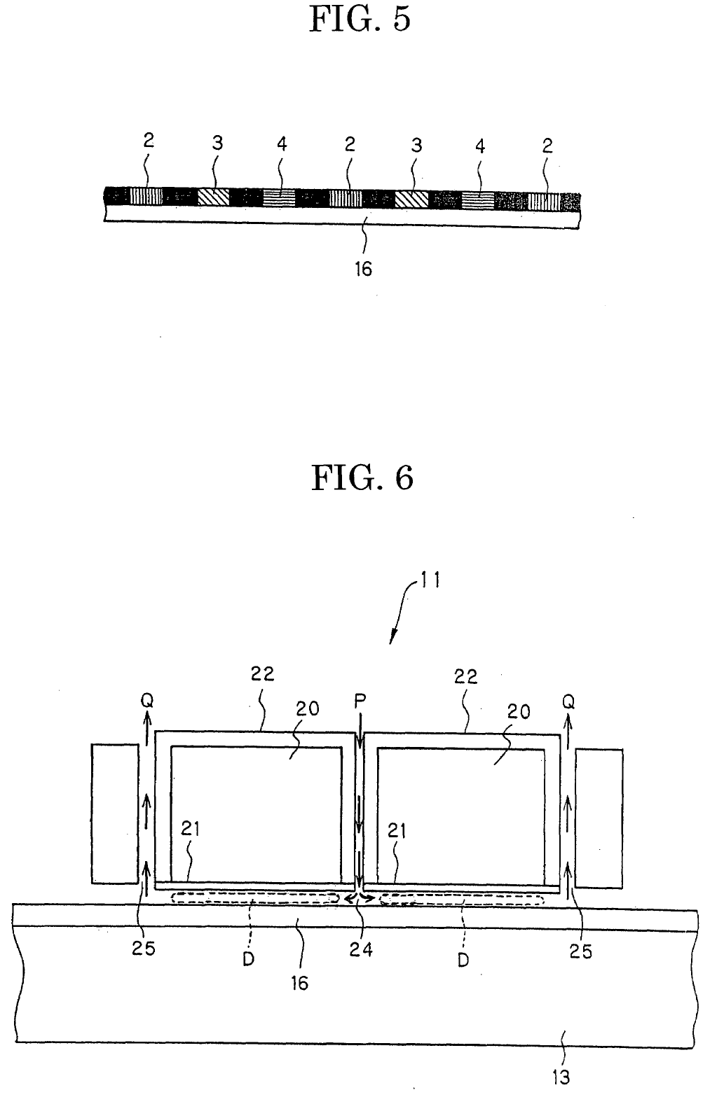

The workpiece material (glass substrate) 16 having been subjected to the plasma processing step in the plasma processing device 10 used in the plasma processing method according to the present embodiment as described above is delivered to a processing device for ink film forming step by means of an ink-jet method as a next process. FIG. 5 is an enlarged sectional view showing the workpiece material (glass substrate) 16 which has been subjected to an ink film forming step by means of the ink-jet method. As shown in FIG. 5, in the ink film forming process by means of the ink-jet method, ink films of red ink 2, green ink 3 and blue ink 4 are formed by means of the ink-jet method on the glass substrate 16 to which ink-attracting quality is given between the black matrices 1 to which ink-shedding quality is given by means of the plasma processing as described above. As an ink film forming device by using an ink-jet method, there can be used a bubble-jet® type using an electricity-heat conversion material as an energy generating element or a piezo-jet type using a piezoelectric element.

As a means for lifting the workpiece material (glass substrate) 16, when delivering the workpiece material (glass substrate) 16 having been subjected to the plasma processing step in the plasma processing device 10 used in the plasma processing method according to the present embodiment to the ink film forming step by means of the ink-jet method by means of a delivery arm (not shown), a lifting frame 14 is provided. As shown in the figure, this lifting frame 14 lifts the workpiece material (glass substrate) with the periphery thereof as a fulcrum. Moreover, this lifting frame 14 is connected to an actuator 15 as a driving source for lifting the lifting frame 14. When the workpiece material (glass substrate) 16 is being subjected to the plasma processing, the lifting frame 14 is arranged so as not to come into contact with the workpiece material (glass substrate) 16. Further, when the lifting frame 14 lifts the workpiece material (glass substrate) 16, the head electrode 11 retracts. As shown in FIG. 2, the lifting frame 14 is arranged substantially on the entire periphery of four sides of the workpiece material (glass substrate) 16 except a space through which the delivery arm (not shown) is inserted. However, the lifting frame 14 may be arranged so as to lift the workpiece material (glass substrate) 16 only at the two sides thereof.

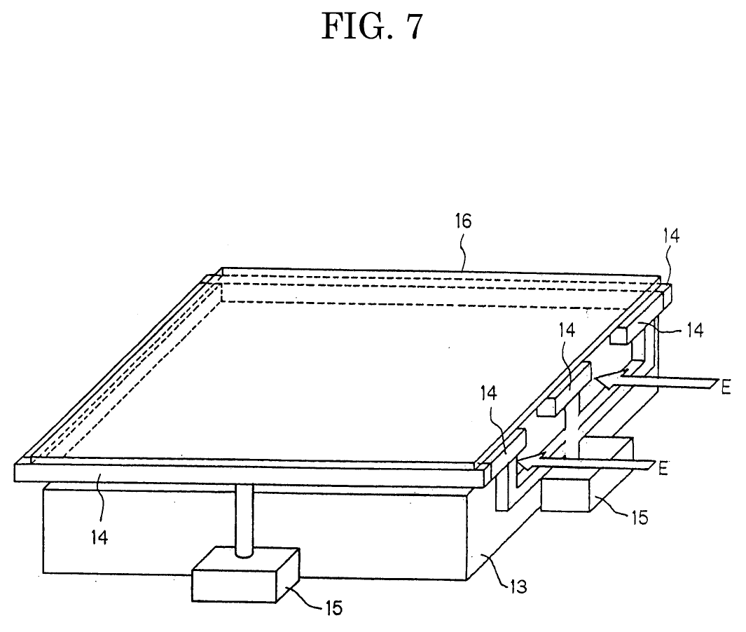

FIG. 7 is a view showing a state in which the workpiece material (glass substrate) 16 is lifted by the lifting frame 14 in the plasma processing device 10 used in the plasma processing method according to the present embodiment. After the plasma processing step by the plasma processing device 10 has been completed, the workpiece material (glass substrate) 16 is delivered to the processing device for the ink film forming step by means of an ink-jet method. At this time, as shown in FIG. 7, a delivery arm (not shown) is inserted under the workpiece material (glass substrate) 16 lifted up by the lifting frame 14, for example, in direction F shown in the figure, and the workpiece material (glass substrate) 16 is delivered to the next step with being laid on the delivery arm.

As shown in FIG. 7, the portion of the workpiece material (glass substrate) 16 with which the lifting frame 14 contacts when lifting the workpiece material (glass substrate) 16 is the periphery of the workpiece material (glass substrate) 16. This periphery lies outside the effective utilization areas in which the black matrices of the workpiece material (glass substrate) 16 are formed. When manufacturing the workpiece material (glass substrate) 16 as a color filter, the effective utilization areas in which the black matrices are formed are clipped from the periphery and are used.

As described above, the workpiece material (glass substrate) 16 is delivered to the ink film forming step by means of the ink-jet method by the lifting frame 14 and the delivery arm. Subsequently, a new workpiece material (glass substrate) 16 is set on the stage (lower electrode) 13 and the lifting frame 14 is returned to the original position thereof by the actuator 15 to prepare for subjecting the new workpiece material (glass substrate) 16 for the plasma processing. In the plasma processing device 10 according to the present embodiment, the workpiece material (glass substrate) 16 is subjected to the plasma processing in the order described above.

Meanwhile, in the plasma processing device 10 used for the plasma processing method according to the present embodiment, no lift pin for lifting the workpiece material (glass substrate) 16 on the stage (lower electrode) 13 is provided in contrast to the conventional plasma processing device 50. Therefore, equal electric discharge characteristics can be obtained in any area of the stage (lower electrode) 13. Accordingly, the plasma processing is performed equally on the workpiece material (glass substrate) 16 that is placed on the stage (lower electrode 13) and plasma-processed, thereby giving proper ink-shedding quality to the lattice portion surfaces (S) of the black matrices on the workpiece material (glass substrate) 16 and giving proper ink-attracting quality to the glass surfaces (T) between the lattices of the black matrices. Thus, the color filter made of the workpiece material (glass substrate) 16 processed by the plasma processing device 10 according to the present embodiment is substantially free from defects such as white spots and color mixture of inks.

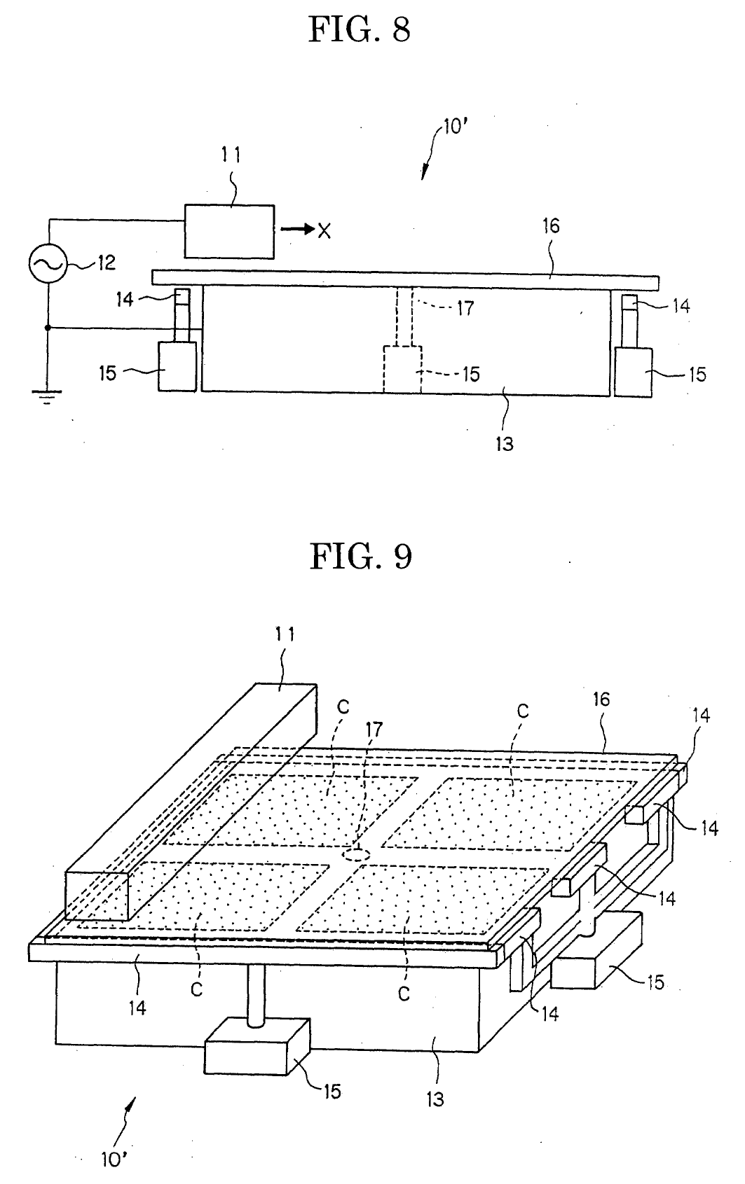

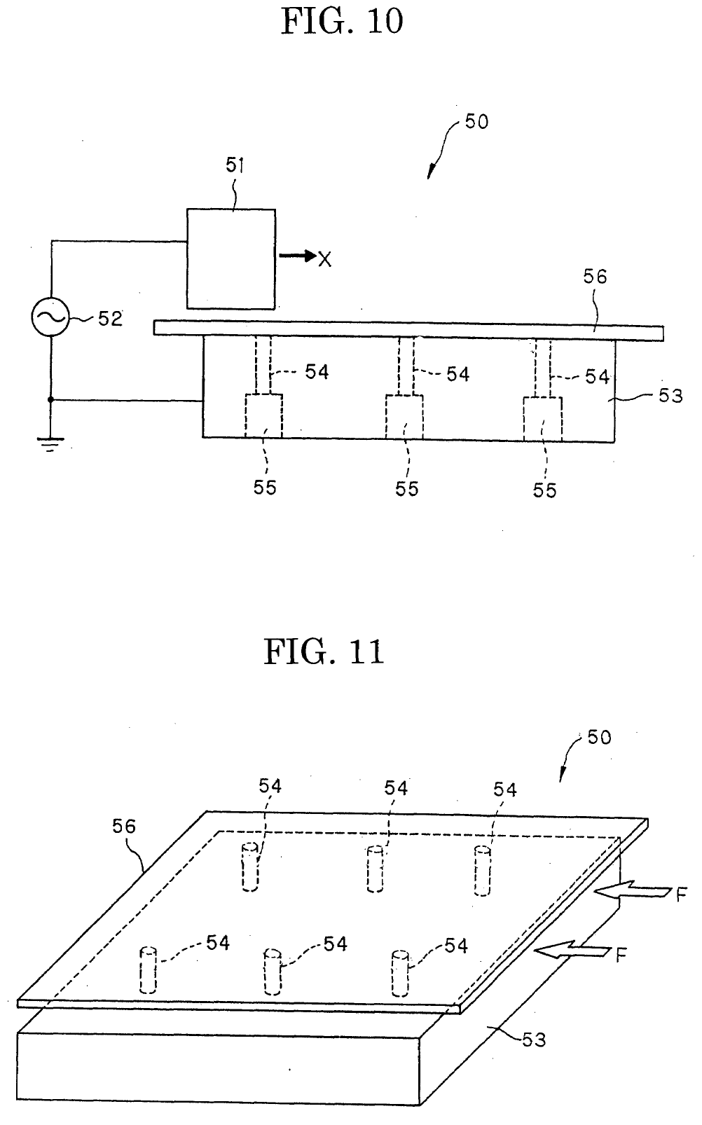

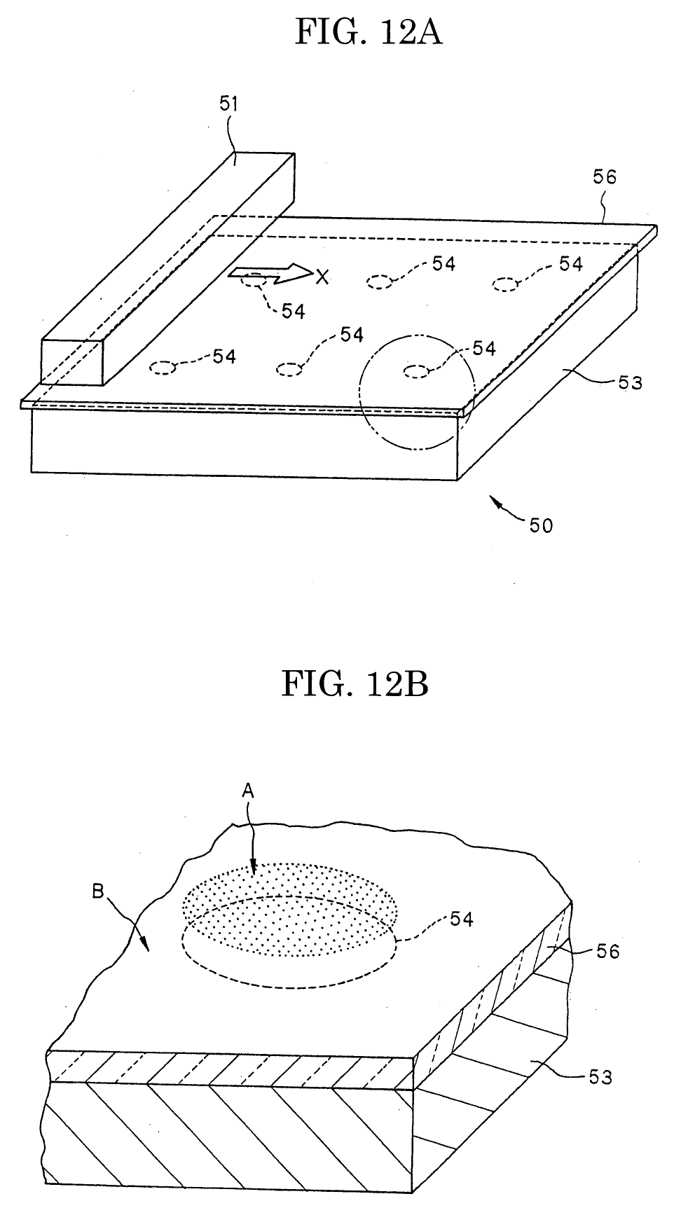

Now, a plasma processing device used for a plasma processing method according to another embodiment of the present invention will be described with reference to the accompanying drawings. FIG. 8 is a view showing the outline of the essential parts of a plasma processing device 10′ used in a plasma processing method according to another embodiment of the present invention. FIG. 9 is a perspective view showing the plasma processing device 10′ used in the plasma processing method according to another embodiment of the present invention.

The present embodiment differs from the previous embodiment in that a lift pin 17 is provided in the stage (lower electrode) 13. This lift pin 17 is a mechanism for lifting the workpiece material (glass substrate) 16 synchronously with a lifting frame 14 and connected to an actuator 15 as a driving source for lifting the lift pin 17.

As well-known, generally, in the manufacturing step of color filters, a plurality of same patterns of black matrices are formed on one sheet of glass substrate. After a plurality of color filters have been formed on the glass substrate through the plasma processing step and the ink film forming step, the color filters are clipped. In such a case, there is effective utilization areas used as color filters and the other unused area in one sheet of the glass substrate. In the present embodiment, the lift pin 17 is arranged to be located below the area other than the effective utilization areas of the workpiece material (glass substrate) 16 when laying the workpiece material (glass substrate) 16 on the stage (lower electrode) 13. FIG. 8 shows an example in which four same patterns of black matrices are formed on one sheet of glass substrate. In the workpiece material (glass substrate) 16, four areas denoted by C are the effective utilization areas in which the patterns of the black matrices are formed and which are processed to be color filters. In the present embodiment, the lift pin 17 is arranged below the area other than these effective utilization areas C. Thus, even if the surface of the workpiece material (glass substrate) 16 on the lift pin 17 has different electric discharge characteristics from the other area in the plasma processing step, proper ink-shedding quality and proper ink-attracting quality are given to the effective utilization areas C. Accordingly, also in the present invention, color filters as finished products are substantially free from defects such as white spots and color mixture of inks. Further, in the present invention, in addition to the lifting frame 14, the lift pin 17 is used to lift the workpiece material (glass substrate) 16. In this manner, the plasma processing device is configured to support the workpiece material (glass substrate) 16 at many points, thereby having a merit of exerting small stress to the workpiece material (glass substrate) 16.

In the above description, the plasma processing device has been described based on the assumption of performing a normal pressure plasma processing. However, it goes without saying that the plasma processing method of the present invention can be applied also to a reduced pressure plasma processing device.

What is claimed is:

1. A plasma processing method, comprising the steps of:
laying a workpiece material on a lower electrode of opposing electrode composed of an upper electrode and a lower electrode;
plasma-processing the workpiece material by means of plasma generated by introducing gas for plasma processing between the upper electrode and the lower electrode and applying voltage between the upper electrode and the lower electrode; and
lifting the plasma-processed workpiece material by lifting means from the lower electrode on which the workpiece material is placed,
wherein the lifting means contacts with the portion of the workpiece material other than effective utilization areas thereof.

2. The plasma processing method according to claim 1, wherein the lifting means contacts with the periphery of the workpiece material that is an area other than the effective utilization areas thereof.

3. The plasma processing method according to claim 2, wherein the lifting means contacts with two sides of the periphery of the workpiece material that is an area other than the effective utilization areas thereof.

4. The plasma processing method according to claim 2, wherein the lifting means contacts with four sides of the periphery of the workpiece material that is an area other than the effective utilization areas thereof.

5. The plasma processing method according to any of claims 1 to 4, wherein the lifting means does not come into contact with the workpiece material at the time of plasma processing.

6. The plasma processing method according to any of claims 1 to 5, wherein the lifting means includes a lift pin coming into contact with the workpiece material in the area of the lower electrode.

7. A color filter manufactured by means of a plasma processing method according to any of claims 1 to 6.

8. Process for manufacturing color filter by means of a plasma processing method according to any of claims 1 to 6.
